(19) United States
(12) Patent Application Publication
(10) Pub. No.: US 2025/0349558 A1
(43) Pub. Date: Nov. 13, 2025

(54) REDISTRIBUTION LINES AND THE METHOD FORMING THE SAME THROUGH STITCHING

(71) Applicant: Taiwan Semiconductor manufacturing Co., Ltd., Hsinchu (TW)

(72) Inventors: Shang-Yun Hou, Jubei City (TW); Chien-Hsun Lee, Chu-tung Town (TW); Tsung-Ding Wang, Tainan (TW); Hao-Cheng Hou, Hsinchu (TW)

(21) Appl. No.: 19/275,727

(22) Filed: Jul. 21, 2025

Related U.S. Application Data
(62) Division of application No. 18/334,650, filed on Jun. 14, 2023.
(60) Provisional application No. 63/490,835, filed on Mar. 17, 2023.

(51) Int. Cl. H01L 21/48; H01L 23/538; H01L 25/065

(52) U.S. Cl. CPC H01L 21/4857; H01L 23/5383; H01L 25/0652; H01L 25/0655

(57) ABSTRACT

A method includes forming a photoresist on a base structure, and performing a first light-exposure process on the photoresist using a first lithography mask. In the first light-exposure process, an inner portion of the photoresist is blocked from being exposed, and a peripheral portion of the photoresist is exposed. The peripheral portion encircles the inner portion. A second light-exposure process is performed on the photoresist using a second lithography mask. In the second light-exposure process, the inner portion of the photoresist is exposed, and the peripheral portion of the photoresist is blocked from being exposed. The photoresist is then developed.

### PRIORITY CLAIM AND CROSS-REFERENCE

This application is a divisional of U.S. patent application Ser. No. 18/334,650, filed Jun. 14, 2023, and entitled “Redistribution Lines and The Method Forming the Same Through Stitching;” which claims the benefit of the following provisionally filed U.S. Patent application: Application No. 63/490,835, filed on Mar. 17, 2023, and entitled “RDL Interposer Stitching,” which application is hereby incorporated herein by reference.

### BACKGROUND

In the packaging of integrated circuits, a plurality of device dies may be bonded on an interposer wafer, which includes a plurality of interposers therein. After the bonding of the device dies, an underfill is dispensed into the gaps between the device dies and the interposer wafer. A curing process may then be performed to cure the underfill. A molding compound can be applied to encapsulate the device dies. The resulting interposer wafer and the top dies thereon are then sawed apart into a plurality of packages. The packages are then bonded to package substrates or printed circuit boards.

With more functions being integrated in the package, the interposer may be formed larger, and problems arise.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3A, 3B, 3C, 4A, 4B, 4C, 5A, 5B, 6, 7A, 7B, 8A and 8B illustrate the views of intermediate stages in the formation of redistribution lines in accordance with some embodiments.

FIGS. 9A and 9B illustrate the schematic photolithography masks with an overlapping ring-shaped region in accordance with some embodiments.

FIG. 10 illustrates the schematic regions formed using two photolithography masks in accordance with some embodiments.

FIGS. 11-14 illustrate the views of intermediate stages in the formation of redistribution lines spaced apart by a non-overlapping region in accordance with some embodiments.

FIG. 15 illustrates a package adopting the stitched redistribution lines in accordance with some embodiments.

FIG. 16 illustrates a redistribution structure adopting the stitched redistribution lines in accordance with some embodiments.

FIGS. 17-19 illustrate the packages adopting the stitched redistribution lines in accordance with some embodiments.

FIG. 20 illustrates a process flow for forming a package component through stitching in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A package component and the method of forming redistribution lines in the package component through stitching are provided. In accordance with some embodiments of the present disclosure, the formation of the redistribution lines includes forming a photoresist, and light-exposing the photoresist through a first light-exposure process (also referred to as photo-exposure process) and a second light-exposure process. The first light-exposure process is performed using a first photolithography mask, wherein an outer region of the photoresist is exposed to form patterns. Throughout the description, the terms “photolithography mask” and “lithography mask” are used interchangeably. An internal region encircled by the outer region is blocked from the exposure by the first photolithography mask. The second light-exposure process is performed using a second photolithography mask, wherein the internal region of the photoresist is exposed to form patterns. The outer region is blocked from the exposure by the second photolithography mask. A ring-shaped region between the inner region and the outer region may be double exposed. The photoresist is then developed to remove some portions, and redistribution lines may be plated in the removed portions of the photoresist.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

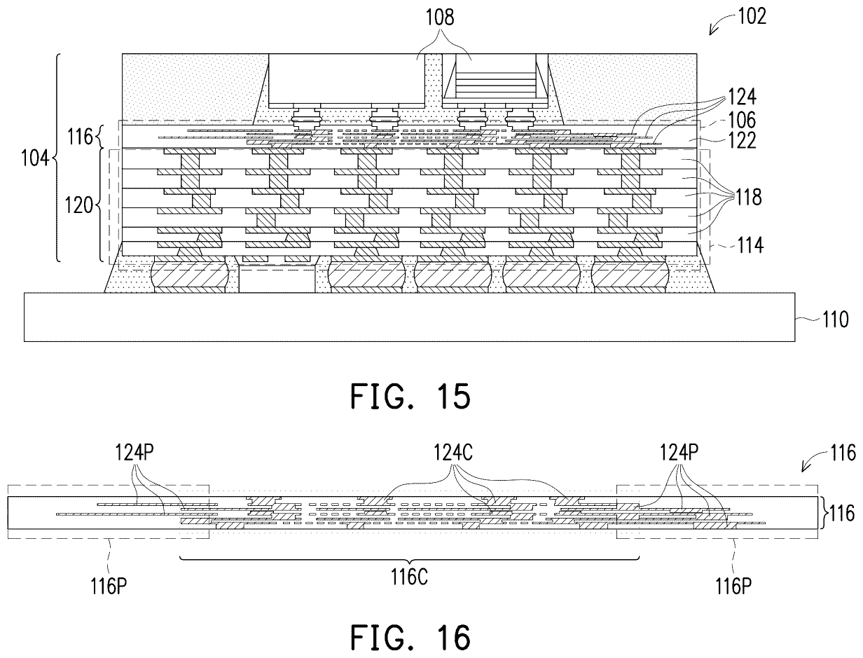

FIG. 15 illustrates package component 102, on which the stitching process of the embodiments may be applied. It is appreciated that although an organic interposer is illustrated as an example, the embodiments of the present disclosure may be applied to other types of large package components including, and not limited to, package substrates, fan-out packages, reconstructed wafers, and the like.

In accordance with some embodiments, package component 102 is a package including package 104 bonding to package component 110. Package component 110 may comprise a package substrate, a printed circuit board, or the like. Package 104 may comprise organic interposer 106, and package components 108 bonding to organic interposer 106. Package components 108 may comprise device dies, multi-die stacks, packages, and/or the like.

In accordance with some embodiments, organic interposer 106 includes a plurality of redistribution structures, which may be formed of or comprise different dielectric materials, and may be formed using different formation methods. For example, organic interposer 106 may include redistribution structures 114 and 116. Redistribution structure 116 may be formed on, or may be pre-formed and bonding to, redistribution structure 114. Redistribution structure 114 may include dielectric layers 118 and redistribution lines (RDLs) 120 formed in dielectric layer 118. Redistribution structure 116 may include dielectric layers 122 and RDLs 124 formed in dielectric layer 122. In accordance with some embodiments, dielectric layers 118 and 122 are organic dielectric layers comprising organic dielectric materials such as polyimide, polybenzoxazole (PBO), benzocyclobutene (BCB), or the like. RDLs 120 and 124 may be formed of or comprise copper, nickel, aluminum, or the like.

FIG. 16 illustrates a magnified view of redistribution structure 116, which may be formed adopting the embodiments of the present disclosure. Redistribution structure 116 may include a region 116C, and a region 116P encircling (and partially overlapping) region 116C when viewed in a top view of redistribution structure 116. In accordance with some embodiments, in each or at least some of the RDLs 124 in redistribution structure 116, the redistribution lines 124C in the region 116C are fine redistribution lines having smaller widths (when viewed in the top view). The redistribution lines 124C in the region 116C are formed using first lithography masks and through first photolithography processes. The redistribution lines 124P in the region 116P are coarse redistribution lines having greater widths than the fine redistribution lines. The redistribution lines 124P are formed using second lithography masks separated from the first lithography masks, and through second photolithography processes separated from the first lithography processes.

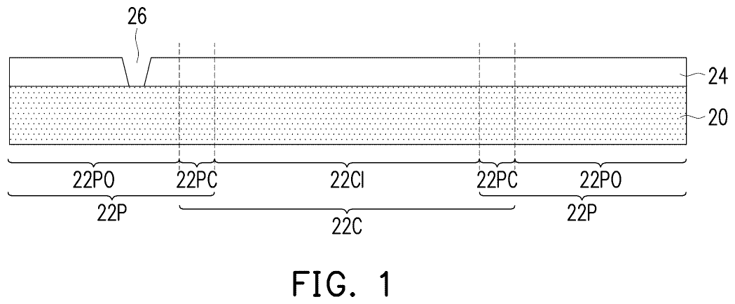

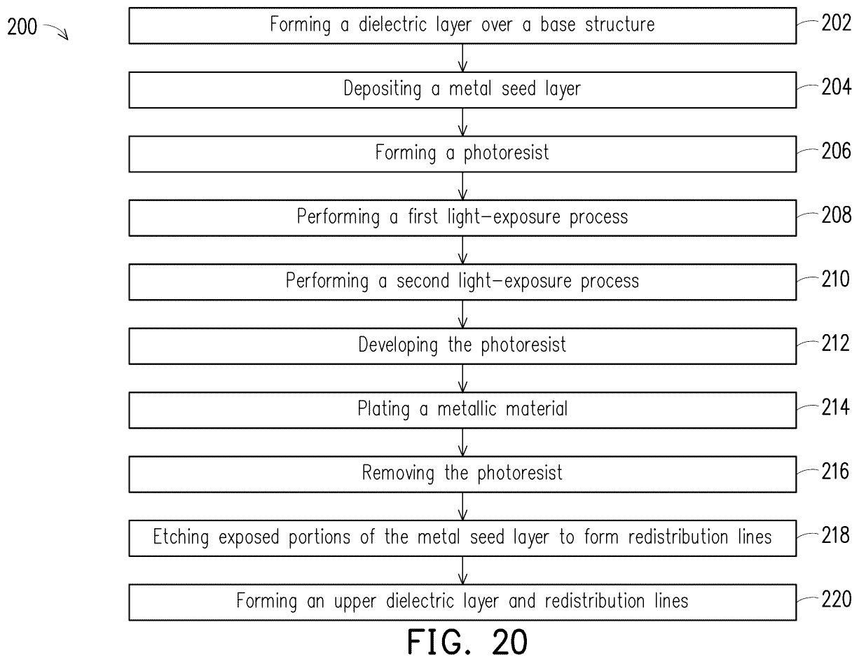

FIGS. 1, 2, 3A, 3B, 3C, 4A, 4B, 4C, 5A, 5B, 6, 7A, 7B, 8A and 8B illustrate the views of intermediate stages in the formation of redistribution lines in an RDL layer in accordance with some embodiments. The corresponding processes are also reflected schematically in the process flow shown in FIG. 20.

FIG. 1 illustrates a cross-sectional view of base structure 20. The details of base structure 20 are not illustrated, and are explained briefly herein. In accordance with some embodiments of the present disclosure, base structure 20 may include a carrier, a release film on the carrier, and a buffer dielectric layer on the release film. The carrier may be a glass carrier. The release film may be a light-to-heat conversion (LTHC) film, which may be decomposed when subject to the heat of a radiation source (such as laser). The buffer dielectric layer may be a polymer layer such as a PBO layer. The base structure 20 may (or may not) include one or a plurality of RDL layers.

In accordance with alternative embodiments, base structure 20 is a part of an interposer wafer, which does not include active devices such as transistors and diodes, and may or may not include passive devices. The interposer wafer includes a plurality of interposers, which include conductive features (such as metal lines, metal vias, and metal pads) on the opposite sides of a semiconductor substrate. In accordance with yet alternative embodiments, base structure 20 is a device wafer including integrated circuit devices, which are formed on the top surface of a semiconductor substrate in the device wafer. Example integrated circuit devices include Complementary Metal-Oxide Semiconductor (CMOS) transistors, resistors, capacitors, diodes, and/or the like.

Base structure 20 includes a center portion in inner patterned-region 22C, and a peripheral portion in outer patterned-region 22P. Throughout the description, the terms “center” and “peripheral” are relative terms, and refers to the inner portion and the outer portions of a region on which lithography processes are performed. For example, since the formation of the features on the base structure 20 may include a plurality of light-exposure processes, each corresponding to a part of the base structure, there are a plurality of center regions and a plurality peripheral regions encircling the respective center regions. Throughout the description, the terms “center portion” and “center region” may also be referred to as an “inner portion” and an “inner region,” respectively.

The outer patterned-region 22P and the inner patterned-region 22C have an overlapping region 22PC, which is also the region in which stitching occurs, and hence is referred to as stitching region 22PC. The stitching region 22PC may have a ring shape in the top view. The portion of the outer patterned-region 22P outside of the stitching region 22PC is referred to as peripheral portion 22PO or peripheral region 22PO. The portion of inner patterned-region 22C inside the stitching region 22PC is referred to as center portion 22CI or center region 22CI. When the redistribution structure 116 as shown in FIG. 16 is to be formed, the outer patterned-region 22P and the inner patterned-region 22C in FIG. 1 also correspond to the region 116P and the region 116C, respectively, in FIG. 16.

The outer patterned-region 22P and the inner patterned-region 22C are alternatively referred to as a first reticle field region and a second reticle field region, respectively, which are the regions in which patterns are formed in a first lithography process and a second lithography process, respectively.

Further referring to FIG. 1, dielectric layer 24 is formed on base structure 20, and is then patterned to form via openings 26. The respective process is illustrated as process 202 in the process flow 200 as shown in FIG. 20. In accordance with some embodiments of the present disclosure, dielectric layer 24 is formed of or comprises an organic material, which may be a polymer. The organic material may also be a photo-sensitive material. For example, dielectric layer 24 may be formed of or comprises polyimide, PBO, BCB, or the like. Although one via openings 26 is illustrated, there may be a plurality of openings 26 formed throughout outer patterned-region 22P and inner patterned-region 22C, depending on the desirable routing.

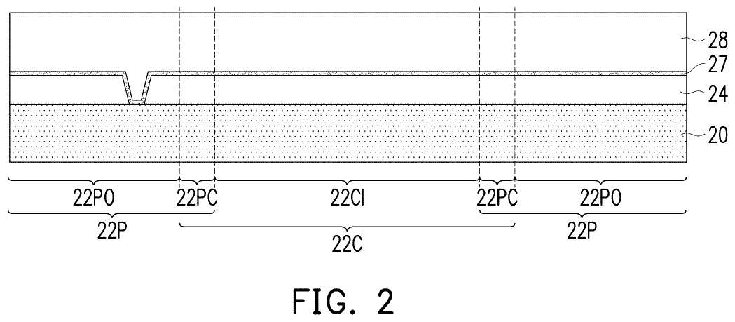

Referring to FIG. 2, a blanket metal seed layer 27 is deposited, and extends into the via openings 26. The respective process is illustrated as process 204 in the process flow 200 as shown in FIG. 20. The metal seed layer 27 may include a titanium layer and a copper layer over the titanium layer. The formation may include physical vapor deposition, for example.

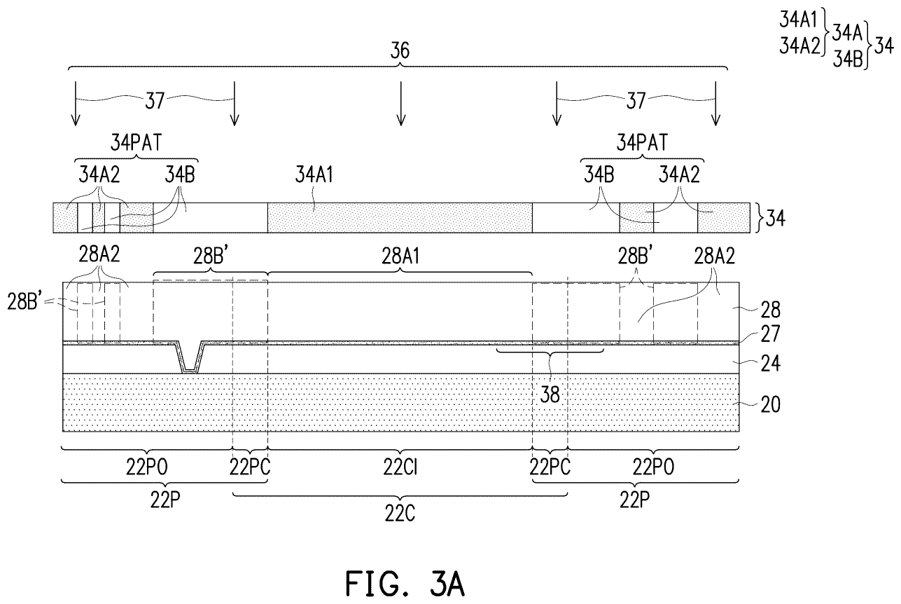

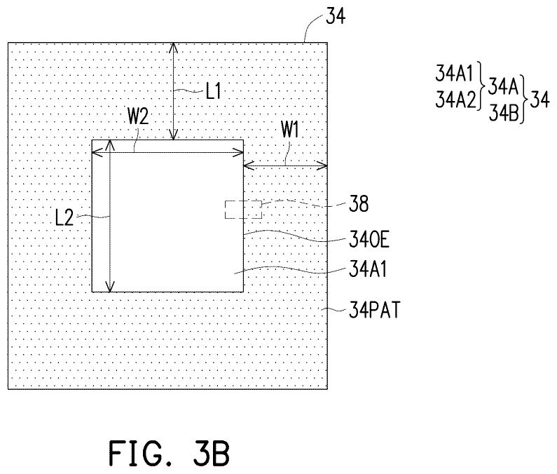

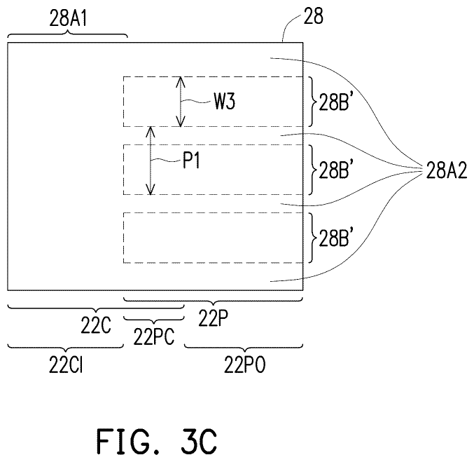

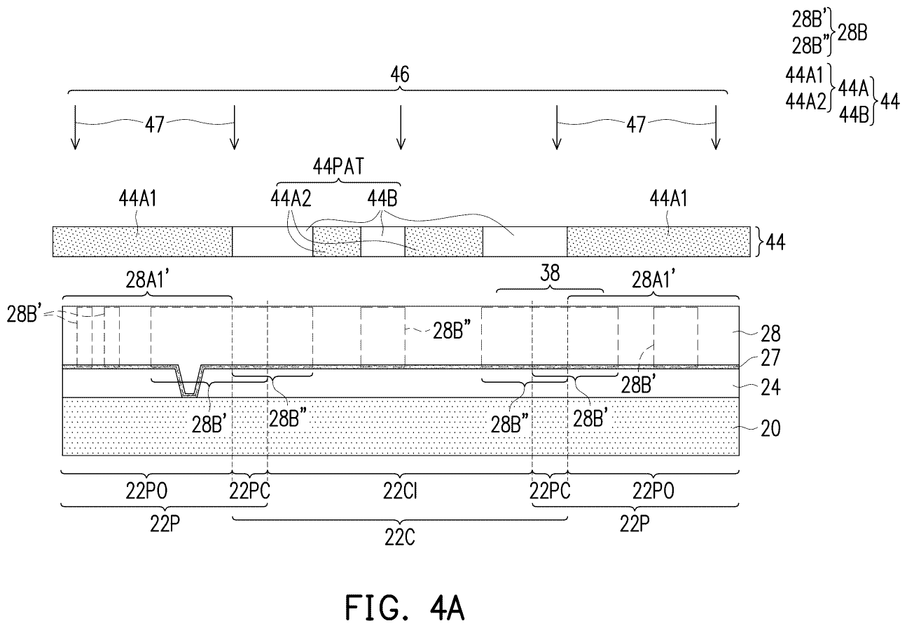

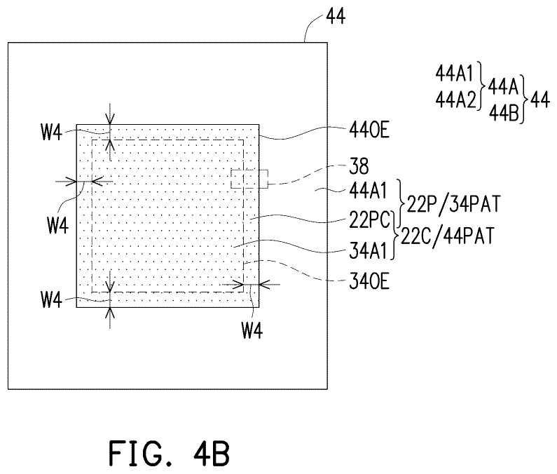

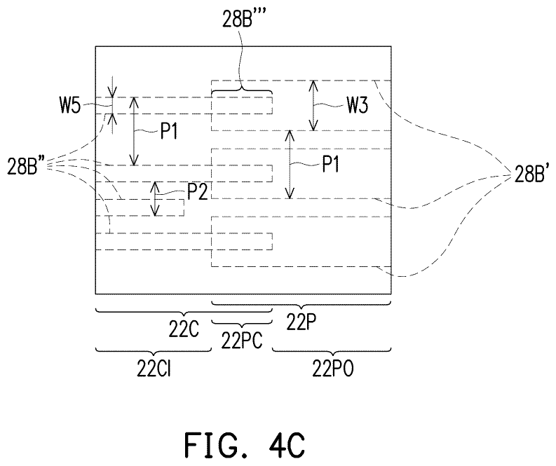

Plating mask 28 is formed over metal seed layer 27. The respective process is illustrated as process 206 in the process flow 200 as shown in FIG. 20. Plating mask 28 may include a photoresist, and may be a single-layer mask, a tri-layer mask, or the like. The subsequently discussed two light-exposure processes are performed on the photoresist, which may be the single photoresist or the top layer of the tri-layer mask. Furthermore, in the subsequently discussed example, it is assumed that the photoresist is a positive photoresist, in which the light-exposed portions are removed, and un-exposed portions remain after the light-exposure processes and a subsequent development process. In accordance with alternative embodiments, plating mask 28 includes a negative photoresist, in which the un-exposed portions are removed, and the light-exposed portions remain after the light-exposure processes and the subsequent development process. The corresponding RDL formation and stitching process for the negative photoresist may be realized by inverting the opaque patterns and transparent patterns in the respective photolithography masks 34 (FIG. 3A) and 44 (FIG. 4A). In subsequent discussion, plating mask 28 is also referred to as photoresist 28 for simplicity.

Referring to FIG. 3A, photolithography mask 34 is placed over photoresist 28. The size of photolithography mask 34 may be large enough to cover the interposer to be formed, which interposer may be the redistribution structure 116 (FIGS. 15 and 16) or other parts of the organic interposer 106 (FIG. 15). Photolithography mask 34 includes opaque portions 34A for blocking light, and transparent portions 34B allowing light to pass through. The transparent portions 34B correspond to the portions of the RDLs that are to be formed in subsequent processes. In accordance with some embodiments, opaque portions 34A include a large continuous portion 34A1 extending continuously throughout the center region 22CI. Opaque portions 34A further includes portions 34A2, which are for defining the patterns of redistribution lines in the RDLs. The transparent portions in photolithography mask 34 are in the outer patterned-region 22P, and are not in the center portion 22CI.

FIG. 3B illustrates a top view of photolithography mask 34 in accordance with some embodiments. Photolithography mask 34 may have a rectangular or square top view shape, and includes a center portion 34A1, and outer-patterned portion 34PAT encircling center portion 34A1. The entire center portion 34A1 is an opaque block, and does not include patterns therein. The outer-patterned portion 34PAT includes the patterns (PAT) of opaque portions 34A2 and transparent portions 34B, both are shown in FIG. 3A. The details of opaque portions 34A2 and transparent portions 34B are not shown in FIG. 3A.

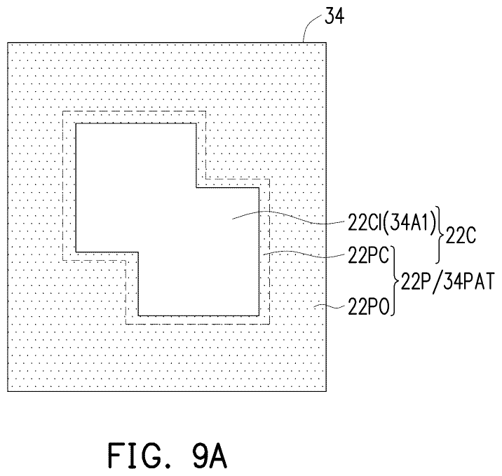

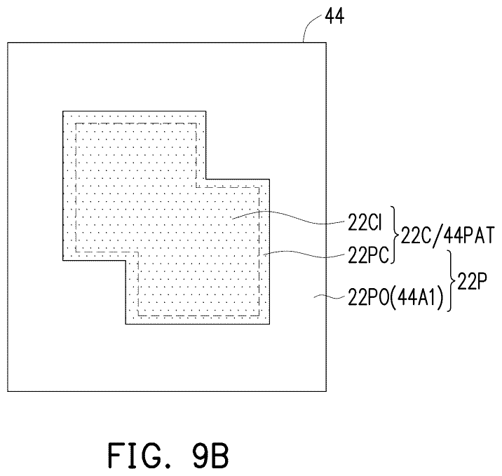

In accordance with some embodiments, the outer-patterned portion 34PAT has length L1 and width W1, and the center portion 34A1 has length L2 and width W2. Each of the ratios L1/L2 and W1/W2 may be in the range between about 1/5 and about 5. In accordance with some embodiments, center portion 34A1 has a rectangular top-view shape, as shown in FIG. 3B. In accordance with other embodiments, center portion 34A1 may have other shapes including, and not limited to, a hexagonal shape, a circular shape, a shape that includes the union of two or more shapes (such as in FIG. 9A), or the like.

Referring back to FIG. 3A, a first light-exposure process 36 is performed by projecting a light beam 37 on photoresist 28 through photolithography mask 34. The respective process is illustrated as process 208 in the process flow 200 as shown in FIG. 20. Photolithography mask 34 is used for defining the light-exposed portions in photoresist 28, wherein the portions of photoresist 28 directly underlying the opaque portions 34A are not exposed, while the portions of photoresist 28 directly underlying the transparent portions 34B are exposed. Since the opaque portions 34A1 covers the entire center region 22CI, the portion of photoresist 28 in the entire center region 22CI is not exposed. The portions of photoresist 28 in outer patterned-region 22P (including the stitching region 22PC) are exposed.

As a result of the light-exposure process 36, photoresist 28 includes unexposed portion 28A1, which is a single large portion extending throughout the entire inner patterned-region 22C. Photoresist 28 further includes unexposed portion 28A2 and exposed portions 28B′, which are in outer patterned-region 22P (including stitching region 22PC). Accordingly, the patterns of the to-be-formed RDLs in the outer patterned-region 22P are defined in photoresist 28.

FIG. 3C illustrates a magnified view of a portion of photoresist 28 in accordance with some embodiments. The illustrated portion is in the region 38 in FIG. 3B, and also corresponds to the region 38 in FIG. 3A. In accordance with some embodiments, as shown in FIG. 3C, the exposed portions 28B′ include a plurality of elongated strips, with the lengthwise directions of the elongated strips being perpendicular to the boundary of outer patterned-region 22P.

In accordance with some embodiments, the photolithography mask 34 has a large reticle field covering the entire package component to be formed (such as the entire redistribution structure 116 (FIG. 15)), and the reticle field is large enough to cover the entire organic interposer 106 (FIG. 15). Due to process reasons, it is difficult to form fine redistribution lines with small widths when the large reticle field of photolithography mask 34 is adopted. Accordingly, the exposed portions 28B′ are coarse patterns having large widths. In accordance with some embodiments, the width W3 of the exposed portions 28B′, which width W3 is also the width of the future RDLs, may be in the range between about 10 μm and about 50 μm. The pitch P1 of the exposed portions 28B′ may also be large, and may be in the range between about 20 μm and about 100 μm. It is appreciated that the terms “fine” and “coarse” are relative terms.

FIGS. 4A, 4B, and 4C illustrate the views of a second light-exposure process using a second lithography mask. Referring to FIG. 4A, photolithography mask 44 is placed over photoresist 28. The area of the patterned portions of photolithography mask 44 is smaller than photolithography mask 34, and covers a center portion, but not all, of the package component to be formed (such as redistribution structure 116 (FIGS. 15 and 16) and the entire organic interposer 106 (FIG. 15)). Photolithography mask 44 includes opaque portions 44A for blocking light, and transparent portions 44B allowing light to pass through. In accordance with some embodiments, opaque portions 44A include a large continuous portion 44A1 extending throughout the entire peripheral region 22PO. Opaque portions 44A further includes portions 44A2, which are for defining the patterns of RDLs. The transparent portions 44B are in the inner patterned-region 22C.

FIG. 4B illustrates a top view of photolithography mask 44 in accordance with some embodiments. The top view area, the length, and the width of photolithography mask 44 may be the same as the top view area, the length, and the width, respectively, of photolithography mask 34. In accordance with some embodiments, photolithography mask 44 has a rectangular or square top-view shape, and includes ring-shaped portion 44A1, and patterned portion 44PAT encircled by ring-shaped portion 44A1. The entire ring-shaped portion 44A1 is opaque, and does not have transparent portions therein. The patterned portion 44PAT includes the patterns (PAT) of opaque portions 44A2 and transparent portions 44B, both are shown in FIG. 4A. The details of opaque portions 44A2 and transparent portions 44B are not shown in FIG. 4B.

In accordance with some embodiments, the patterned portion 44PAT has an outer boundary 440E, which defines stitching region 22PC in combination with the boundary 340E (also refer to FIG. 3B). The overlapping regions of the patterned portion 44PAT and the patterned portion 34PAT form the ring-shaped region 22PC, which is also shown in FIGS. 4A and 4C. In accordance with some embodiments, the ring-shaped stitching region 22PC has width W4, which may be in the range between about 5 μm and about 80 um. In accordance with some embodiments, different portions (such as the four sides as illustrated) of the ring-shaped portion of the photolithography mask 44 has a same width W4.

Referring back to FIG. 4A, a second light-exposure process 46 is performed by projecting a light beam 47 on photoresist 28 through photolithography mask 44. The respective process is illustrated as process 210 in the process flow 200 as shown in FIG. 20. Photolithography mask 44 is used for defining the light-exposed portions in photoresist 28, wherein the portions of photoresist 28 directly underlying the opaque portions 44A are not exposed, while the portions of photoresist 28 directly underlying the transparent portions 44B are exposed. Since the opaque portions 44A1 covers the entire peripheral region 22PO, the portion of photoresist 28 in the entire peripheral region 22PO is not exposed. The portions of photoresist 28 in inner patterned-region 22C (including the stitching region 22PC) are exposed.

In accordance with some embodiments, the light beam for the light-exposure process is projected on the entire photolithography mask 44. In accordance with alternatively embodiments, the projected area includes the patterned portion 44PAT and the inner parts of opaque portion 44A1, while the outer parts of the opaque portion 44A1 do not receive the light beam. This enables the focusing of the light beam 37 to a smaller reticle field.

As a result of the light-exposure process 46, some portions 28B″ of photoresist 28 are light-exposed. The exposed portions 28B″ includes some of the previously unexposed portion 28A1 (FIG. 3A), and some previously exposed portions 28B′ in stitching regions 22PC. Accordingly, more patterns of the to-be-formed RDLs in inner patterned-region 22C are defined in photoresist 28. The stitching region 22PC is also the overlapping region of the patterned regions 34PAT and 44PAT. Some parts of photoresist 28 in the stitching region 22PC are double exposed. Photoresist 28 further includes portion 28A1′, which is a ring-shaped region overlapped by the opaque portion 44A1. Portion 28A1′ is not exposed in the light-exposure process 46.

FIG. 4C illustrates a magnified view of a portion of photoresist 28 in accordance with some embodiments. The illustrated portions are in the region 38 in FIG. 4B, and also correspond to the region 38 in FIG. 4A. In accordance with some embodiments, the exposed portions 28B″ include a plurality of strips, with the lengthwise directions of the strips being perpendicular to the boundary of inner patterned-region 22C.

In accordance with some embodiments, the patterned portion 44PAT of the photolithography mask 44 has a small reticle field covering a part, but not all, of redistribution structure 116 (FIG. 15) and organic interposer 106 (FIG. 15). Due to process reasons, it is possible to form fine redistribution lines for small reticle fields. Accordingly, the exposed portions 28B″ may be fine patterns having small widths. In accordance with some embodiments, the width W5 of the exposed portions 28B″, which width W5 is also the width of the future fine RDLs, may be in the range between about 2 μm and about 10 μm. It is appreciated that although the illustrated exposed portions 28B″ have pitch P1, it is possible to form the exposed portions 28B″ have smaller pitches. For example, pitch P2 of the exposed portions 28B″ may also be small, and may be in the range between about 4 μm and about 20 μm.

As shown in FIG. 4C, the portions 28B′″ of photoresist 28 are double exposed, once in light-exposure process 36 (FIG. 3A), and once in light-exposure process 46 (FIG. 4A). Furthermore, width W5 is smaller than width W3 since the exposed portions 28B″ are for forming fine redistribution lines, and the exposed portions 28B′ are for forming coarse redistribution lines. The ratio W5/W3 may be in the range between about 1/1.5 and about 1/10.

In above-discussed example, photolithography mask 34, which is for forming coarse redistribution lines, is illustrated as being used for a photolithography process before the use of photolithography mask 44, which is for forming fine redistribution lines. It is appreciated that the order of the use of photolithography masks 34 and 44 may be inversed in accordance with alternative embodiments.

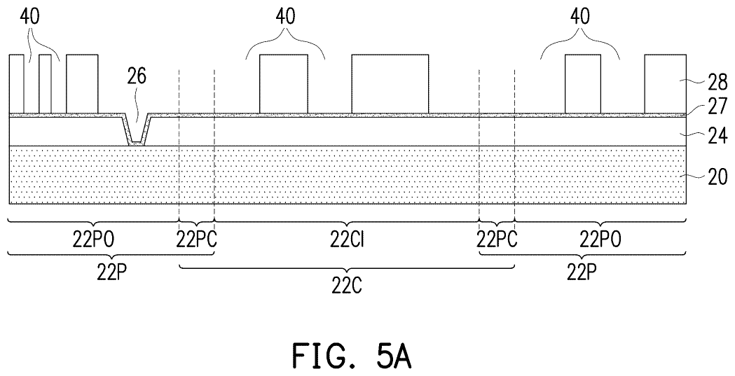

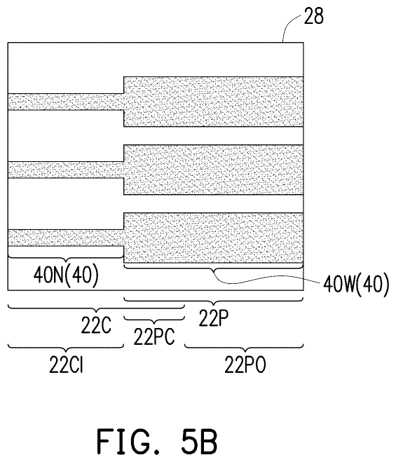

Next, a photoresist development process is performed, and the exposed portions 28B (including portions 28B′ and 28B″) are removed, and unexposed portions 34A remain. The respective process is illustrated as process 212 in the process flow 200 as shown in FIG. 20. In the embodiments in which plating mask 28 is a tri-layer mask, the bottom layer of the tri-layer mask may be etched using the developed photoresist as an etching mask, and the bottom layer may be used as the plating mask. A plurality of trenches 40 are formed in photoresist 28, exposing the underlying metal seed layer 27. The resulting structure is shown in FIG. 5A. The exposed portions of metal seed layer 27 include the portions in outer patterned-region 22P and the portions in inner patterned-region 22C, with stitching region 22PC being the overlapping region of the outer patterned-region 22P and the inner patterned-region 22C.

FIG. 5B illustrates a top view of some portions of trenches 40, which continually extend from outer patterned-region 22P into inner patterned-region 22C. The portion of the photoresist 28 in center region 22CI has narrower trench portions 40N. The portion of the photoresist 28 in peripheral portion 22PO has wider trench portions 40W. The portion of the photoresist 28 in stitching region 22PC also has wider trench portions 40W.

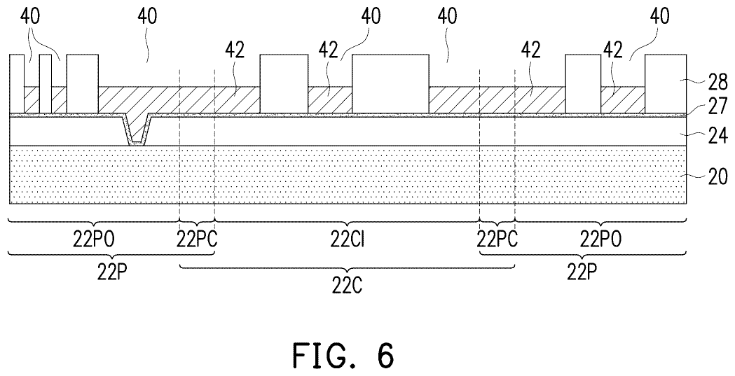

FIG. 6 illustrates a plating process to plate metallic material 42 in trenches 40 in accordance with some embodiments. The respective process is illustrated as process 214 in the process flow 200 as shown in FIG. 20. The plating process is selective, and the metallic material 42 is plated on the exposed portions of metal seed layer 27. The plating process may be performed through electro-chemical plating, electro-less plating, or the like. Metallic material 42 may include copper, a copper alloy, aluminum, palladium, or the like.

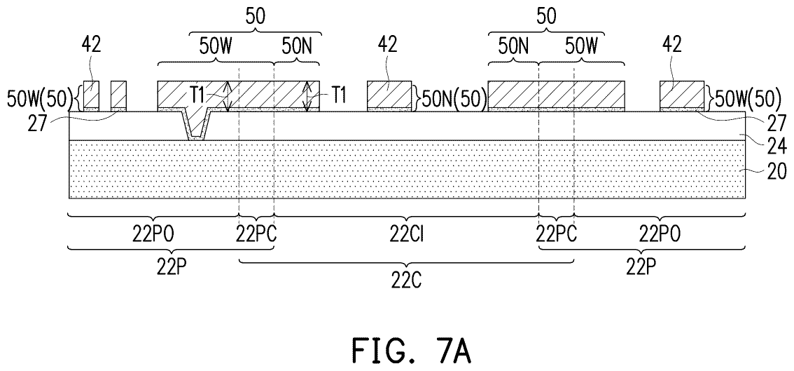

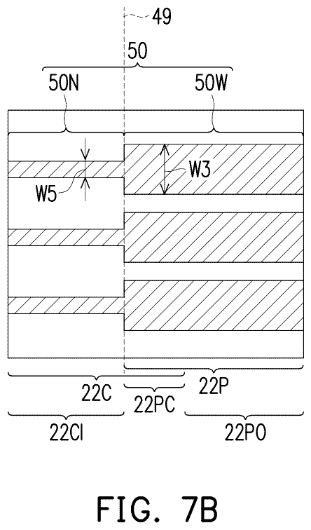

Next, photoresist 28 is removed, for example, in an ashing process or a chemical etching process, and some portions of metal seed layer 27 are exposed. The respective process is illustrated as process 216 in the process flow 200 as shown in FIG. 20. The exposed portions of metal seed layer 27 are then etched. The respective process is illustrated as process 218 in the process flow 200 as shown in FIG. 20. Metallic material 42 and the portions of metal seed layer 27 directly underlying metallic material 42 are collectively referred to as redistribution lines 50, as shown in FIG. 7A. The redistribution lines 50 in the same layer are collectively referred to as a redistribution layer. Redistribution lines 50 include narrower portions 50N in center region 22CI, and wider portions 50W in the peripheral region 22PO and stitching region 22PC. Narrower portions 50N and wider portions 50W may have a same thickness T1, which may be in the range between about 1 μm and about 10 μm.

FIG. 7B illustrates a top view of some of the redistribution lines 50 in accordance with some embodiments. As shown in FIG. 7B, redistribution lines 50 have wider portions 50W joining the respective narrower portions 50N. While the joining positions may be identified through the different widths W3 and W5, wider portions 50W are continuously joined to the respective narrower portions 50N, with no distinguishable interfaces. The transition positions transiting from the wider portions 50W to the narrow portions 50N may be aligned to a straight line 49. The straight line 49 is a portion of a closed ring, as can be realized from the discussion of FIG. 4B.

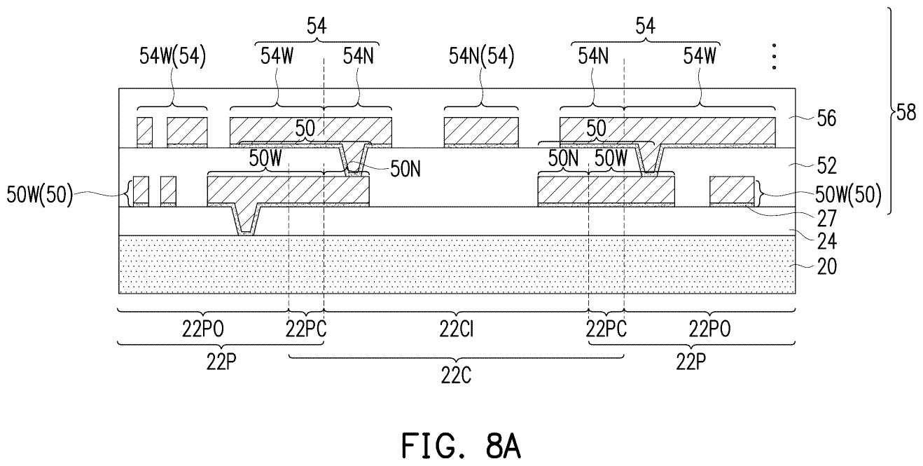

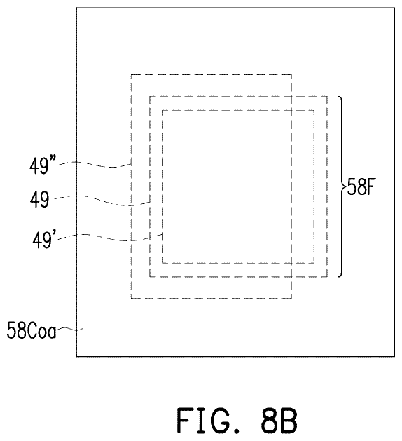

FIG. 8A illustrates the formation of an upper dielectric layer 52, and upper RDLs 54 having via portions extending into dielectric layer 52. The respective process is illustrated as process 220 in the process flow 200 as shown in FIG. 20. In accordance with some embodiments, RDLs 54 are over and electrically connected to RDLs 50. The formation processes of RDLs 54 are essentially the same as the formation processes of RDLs 50, which includes the use of a first lithography mask in a first lithography process, and a second lithography mask in a second lithography process. The details of the first lithography mask and the second lithography mask may be realized from the discussion of lithography masks 34 and 44, and are not repeated herein. More dielectric layers (such as dielectric layer 56) and RDLs may be formed over dielectric layer 52 and RDLs 54, hence forming redistribution structure 58 that includes a plurality of dielectric layers and redistribution lines layers

FIG. 8B illustrates a top view of the dividing line of coarse redistribution lines and fine redistribution lines in accordance with some embodiments. The redistribution structure 58 includes an inner (fine) region 58F and outer (coarse) region 58Coa, which are separated by dashed lines 49 that forms a ring. In accordance with some embodiments, the redistribution lines are distributed throughout regions 58F and 58Coa. The redistribution lines (such as 50 and 54) in coarse region 58Coa are coarse redistribution lines having greater widths (such as width W3 in FIG. 7B), and may be used as long-range routing lines. The redistribution lines (such as 50 and 54) in fine region 58F are fine redistribution lines having smaller widths (such as width W5 in FIG. 7B), and may be used as short-range routing lines. In accordance with some embodiments, all of the redistribution lines in coarse region 58Coa have greater widths than all of the redistribution lines in fine region 58F.

Since each of the redistribution layers (such as the layer of redistribution lines 50 and the layer of redistribution lines 54) is formed using two lithography masks, the corresponding coarse redistribution lines and the fine redistribution lines in each of the redistribution layer have a corresponding dividing line 49, which forms a ring, and hence is referred to as dividing ring 49. In accordance with some embodiments, the dividing ring 49 in an upper redistribution layer overlaps the dividing ring 49 in the respective lower redistribution layer. For example, all of the dividing rings in different redistribution layers may be vertically aligned. In accordance with alternative embodiments, the dividing ring 49 in an upper redistribution layer offsets from the dividing ring(s) in a lower redistribution layer(s). For example, assuming the redistribution layer of redistribution lines 50 have dividing ring 49, an upper redistribution layer may have dividing ring 49′ or 49″.

FIGS. 9A and 9B schematically illustrate the photolithography masks 34 and 44 for forming redistribution layers in accordance with alternative embodiments. These embodiments are essentially the same as the precedingly discussed embodiments, except that the regions in which fine redistribution lines are to be formed is not a rectangular region. In the illustrated example, the fine redistribution line region includes the union of two rectangular regions.

FIG. 9A illustrates the photolithography mask 34, which includes opaque portion 34A1 and patterned portion 34PAT. The corresponding regions 22CI, 22PC, and 22PO, the inner patterned-region 22C, and the outer patterned-region 22P are also marked. FIG. 9B illustrates the photolithography mask 44, which includes opaque portion 44A1 and patterned portion 44PAT. The corresponding regions 22CI, 22PC, and 22PO, the inner patterned-region 22C, and the outer patterned-region 22P are also marked.

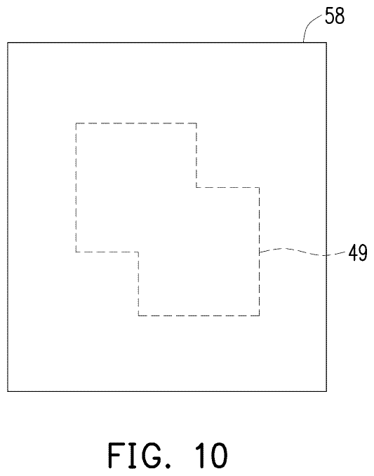

FIG. 10 illustrates a respective redistribution structure 58 (which includes a redistribution lines 50 and 54 as discussed in preceding embodiments) formed using the photolithography masks 34 and 44. The dividing lines 49 of the coarse redistribution lines and fine redistribution lines (of one layer of redistribution lines) are illustrated in accordance with some embodiments. The dividing lines of other layers of redistribution lines may overlap or may offset from the dividing lines 49, same as what is shown in FIG. 8B.

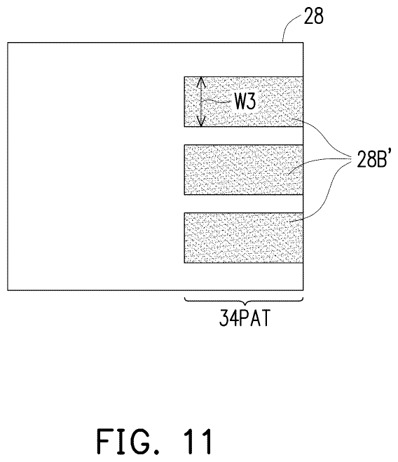

FIGS. 11-14 illustrate the formation of redistribution lines in accordance with alternative embodiments. These embodiments are similar to the embodiments in the preceding embodiments, except that the fine redistribution lines in the fine redistribution line region do not join the coarse redistribution lines in the coarse redistribution line region. Rather, the coarse redistribution line region is separated from the fine redistribution line region by a gap.

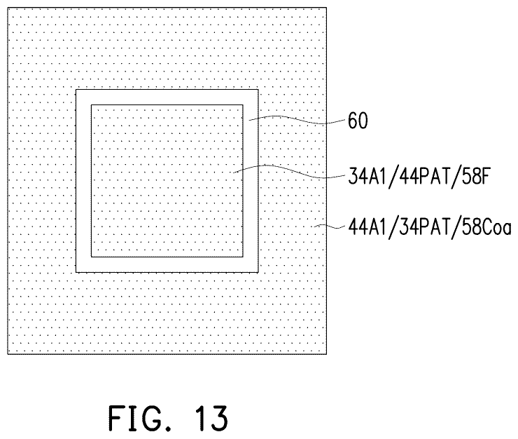

FIG. 13 schematically illustrates the regions of photolithography masks 34 and 44 and the resulting redistribution structure 58 in accordance with some embodiments. An outer region may correspond to the patterned portion 34PAT of photolithography mask 34 and the opaque portion 44A1 of photolithography mask 44. An inner region may correspond to the patterned portion 44PAT of photolithography mask 44 and the opaque portion 34A1 of photolithography mask 34. In the resulting redistribution structure 58, the outer region corresponds to the coarse redistribution line region, in which coarse redistribution lines are formed.

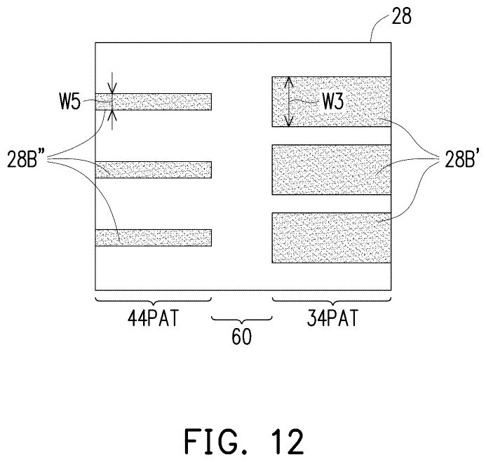

FIG. 11 illustrates some example exposed portions 28B′ of photoresist 28, which have width W3, and are exposed using patterned portion 34PAT (FIG. 13) of photolithography mask 34. In the resulting redistribution structure 58, the inner region corresponds to the fine redistribution line region 58F, in which fine redistribution lines are formed. FIG. 12 illustrates some example exposed portions 28B″ of photoresist 28, which have width W5 that is smaller than width W3. The exposed portions 28″ are exposed using patterned portion 44PAT (FIG. 13) of photolithography mask 44. The exposed portions 28B′ of photoresist 28 are spaced apart from the exposed portions 28B″ by gap 60, which is shown in both of FIGS. 12 and 13.

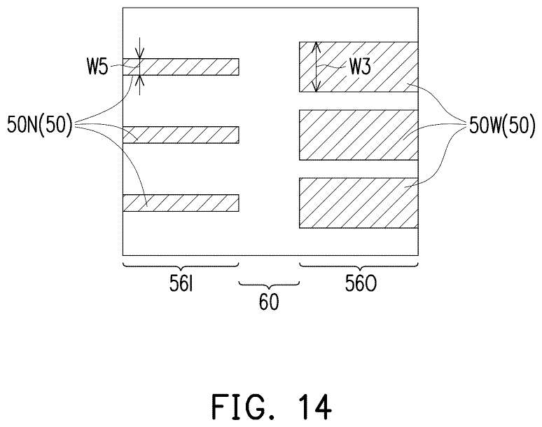

FIG. 14 illustrates the example coarse redistribution lines 50W and fine redistribution lines 50N, which are separated by gap 60. In accordance with some embodiments, in the ring-shaped gap 60 (FIG. 13), no redistribution lines are formed, and hence no coarse redistribution lines 50W are joined to the fine redistribution lines 50N in the same redistribution layer. The ring-shaped gap 60 may include a plurality of portions, which have widths equal to each other.

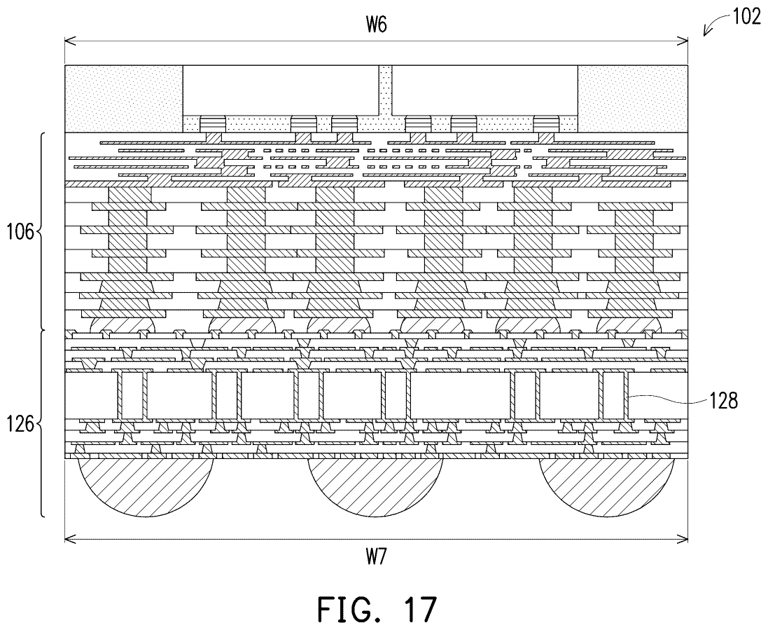

FIGS. 17, 18, and 19 illustrate some example packages 102 in accordance with some embodiments, wherein the stitching process in accordance with some embodiments may be used. The organic interposers 106 are bonded to cored substrates 126, which have cores (conductive pipes) 128 therein. The stitching process may be used for the formation of any (and possibly all) of the redistribution layers in organic interposer 106.

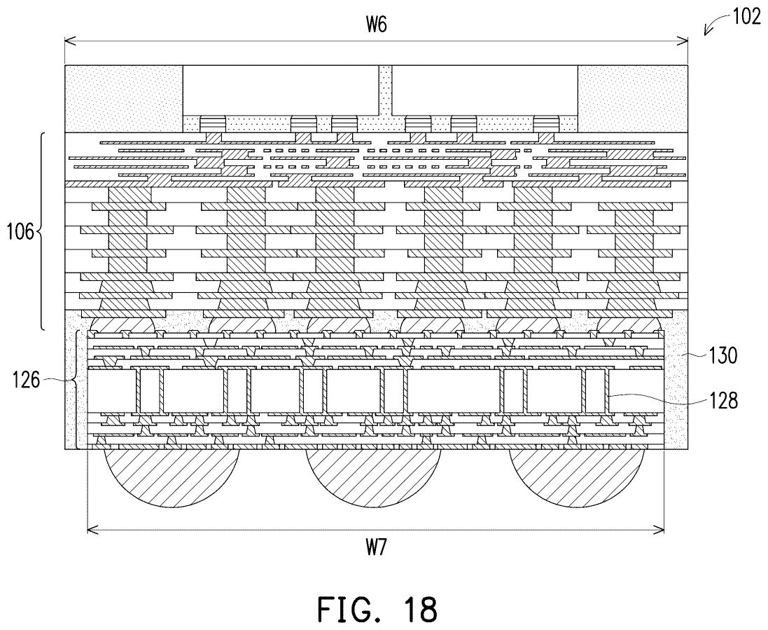

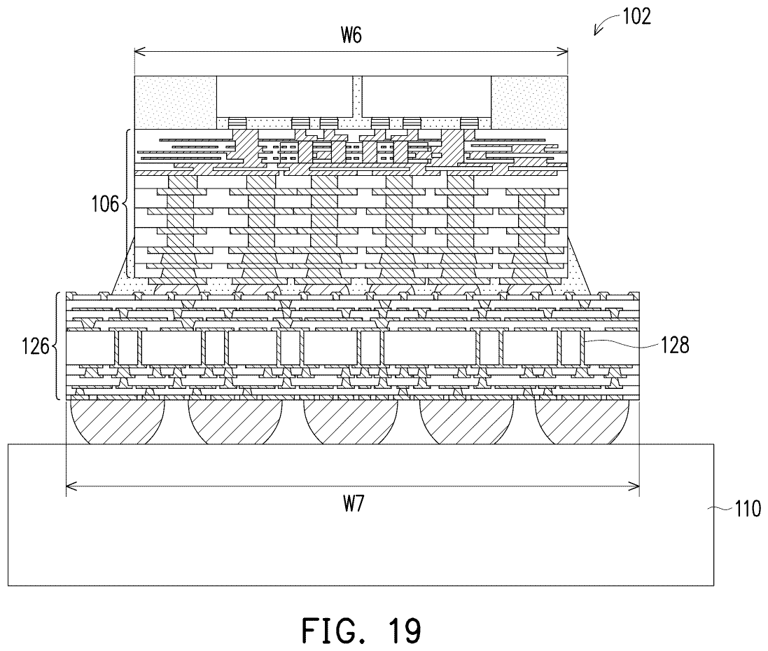

FIGS. 17, 18, and 19 are similar to each other, except the relative widths of organic interposer 106 and cored substrate 126 are different from each other. In FIG. 17, organic interposer 106 has a width W6 the same as the width W7 of the cored substrate 126. In FIG. 18, organic interposer 106 has a width W6 greater than the width W7 of the cored substrate 126. Accordingly, the cored substrate 126 is encapsulated in encapsulant 130, which may be a molding compound. In FIG. 19, organic interposer 106 has a width W6 smaller than the width W7 of the cored substrate 126. An encapsulant (not shown), which may be a molding compound, may be, or may not be, dispensed to encapsulate organic interposer 106 therein. In FIGS. 17, 18, and 19, package component 102 may further be bonded to package component 11o therein.

In above-illustrated embodiments, some processes and features are discussed in accordance with some embodiments of the present disclosure to form a three-dimensional (3D) package. Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

It is appreciated that although the example stitching process as discussed above adopt the formation of RDLs through plating in plating masks, other types of processes such as damascene process may use the stitching methods of the present disclosure. For example, a photoresist may be patterned to form the patterns of metal lines (or vias), wherein the stitching process of the present disclosure may be performed for the light-exposure of the photoresist. A dielectric layer (which may be a low-k dielectric layer) under the photoresist is etched using the photoresist as the etching mask. Metal lines may then be formed in the dielectric layer through damascene processes, which includes depositing a conductive material and then performing a planarization process to remove excess portions of the conductive material over the dielectric layer.

Furthermore, in the illustrated examples, the outer patterned-region fully encircles the inner patterned-region, which means that the inner patterned-region overlaps the inner portions, and does not extend to the outer edges, of the outer patterned-region. In accordance with other embodiments, the inner patterned-region may extend to one outer edge of the outer patterned-region. This means that the stitching region forms a first U-shape, and the outer patterned-region forms another U-shape outlining the first U-shape. In accordance with yet other embodiments, the inner patterned-region may extend to two outer edges of the outer patterned-region, with the two outer edges forming a L-shape. This means that the stitching region forms an L-shape.

Also, although an organic interposer is used as an example to explain where the stitching process can be applied, the stitching process may also be used on all other applicable package components including, and not limited to, device dies/wafers, silicon interposers (with silicon substrates), package substrates, the redistribution structures of reconstructed wafers, fan-out packages, and the like.

The embodiments of the present disclosure have some advantageous features. Two lithography masks are adopted, with one having a reticle field smaller than the other, and the patterns of coarse redistribution lines and fine redistribution lines are defined by the two lithography masks. Otherwise, to form the redistribution lines, four photo-exposure processes and four lithography masks may be needed to form the large redistribution structure and to perform the stitching. The processes for forming the redistribution lines are thus simplified, while the routing requirement can still be met.

In accordance with some embodiments of the present disclosure, a method comprises forming a photoresist on a base structure; performing a first light-exposure process on the photoresist using a first lithography mask, wherein in the first light-exposure process, an inner portion of the photoresist is blocked from being exposed, and a peripheral portion of the photoresist is exposed, and wherein the peripheral portion encircles the inner portion; performing a second light-exposure process on the photoresist using a second lithography mask, wherein in the second light-exposure process, the inner portion of the photoresist is exposed, and wherein the peripheral portion of the photoresist is blocked from being exposed; and developing the photoresist.

In an embodiment, the method further comprises forming first features based on first patterns in the peripheral portion, wherein the first features are formed in the first light-exposure process, and wherein the first features are coarse features having first widths; and forming second features based on second patterns in the inner portion, wherein the second features are formed in the second light-exposure process, and wherein the second features are fine features having second widths smaller than the first widths. In an embodiment, a first conductive feature in the first features and a second conductive feature in the second features are parts of a continuous feature. In an embodiment, the method further comprises forming a seed layer over the base structure; and performing a plating process to form redistribution lines in the photoresist.

In an embodiment, the inner portion is spaced from the peripheral portion by a stitching portion, and wherein some portions of the photoresist in the stitching portion are double exposed. In an embodiment, the stitching portion forms a full ring encircling the inner portion. In an embodiment, the stitching portion includes four portions joined to form a rectangle, and wherein the four portions have a same width. In an embodiment, the inner portion has a rectangular shape. In an embodiment, the base structure comprises parts of an organic interposer, and the organic interposer comprises organic dielectric layers and redistribution lines in the organic dielectric layers.

In an embodiment, the inner portion and the peripheral portion are spaced apart from each other by a ring-shaped portion of the photoresist, and wherein in both of the first light-exposure process and the second light-exposure process, the ring-shaped portion is blocked from being exposed. In an embodiment, the ring-shaped portion includes four portions joined to form a rectangle, and wherein the four portions have a same width. In an embodiment, the first lithography mask and the second lithography mask have a same top-view area.

In accordance with some embodiments of the present disclosure, a structure comprises a package component comprising a dielectric layer; and a first plurality of conductive features in a first region of the dielectric layer, wherein the first plurality of conductive features have first widths; and a second plurality of conductive features in a second region of the dielectric layer, wherein the second plurality of conductive features have second widths greater than the first widths, and wherein the second region of the dielectric layer is a ring-shaped region encircling the first region.

In an embodiment, all conductive features in the second region of the dielectric layer are wider than all conductive features in the first region of the dielectric layer. In an embodiment, some of the second plurality of conductive features are joined to some of the first plurality of conductive features. In an embodiment, joining points where the second plurality of conductive features join corresponding ones of the first plurality of conductive features are aligned to a ring. In an embodiment, the ring has a rectangular top-view shape.

In accordance with some embodiments of the present disclosure, structure comprises a dielectric layer; a first plurality of conductive features in a first part of the dielectric layer; and a second plurality of conductive features in a second part of the dielectric layer, wherein in a top view of the structure, the second plurality of conductive features are wider than the first plurality of conductive features, and wherein the first plurality of conductive features are encircled by, and are joined to, respective ones of the second plurality of conductive features. In an embodiment, joining positions where the first plurality of conductive features are joined to the corresponding ones of the second plurality of conductive features are aligned to a ring. In an embodiment, the first plurality of conductive features and the second plurality of conductive features are elongated and have lengthwise directions perpendicular to respective portions of the ring.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A structure comprising:
a package component comprising:
a dielectric layer; and
a first plurality of conductive features in a first region of the dielectric layer, wherein the first plurality of conductive features have first widths; and
a second plurality of conductive features in a second region of the dielectric layer, wherein the second plurality of conductive features have second widths greater than the first widths, and wherein the second region of the dielectric layer is a ring-shaped region encircling the first region.

2. The structure of claim 1, wherein all conductive features in the second region of the dielectric layer are wider than all conductive features in the first region of the dielectric layer.

3. The structure of claim 1, wherein some of the second plurality of conductive features are joined to some of the first plurality of conductive features.

4. The structure of claim 3, wherein joining points where the second plurality of conductive features join corresponding ones of the first plurality of conductive features are aligned to a ring.

5. The structure of claim 4, wherein the ring has a rectangular top-view shape.

6. The structure of claim 1, wherein the package component comprises:
a redistribution structure, wherein the dielectric layer, the first plurality of conductive features, and the second plurality of conductive features are comprised in the redistribution structure; and
a device die electrically coupled to the redistribution structure.

7. The structure of claim 1, wherein the first plurality of conductive features comprise first metal lines, and wherein first top surfaces of the first metal lines are lower than a second top surface of the dielectric layer.

8. The structure of claim 7, wherein the second plurality of conductive features comprise second metal lines, and the second metal lines comprise second top surfaces coplanar with the first top surfaces of the first plurality of conductive features.

9. The structure of claim 1, wherein ratios of the second widths to the first widths are in a range between about 1.5 and about 10.

10. A structure comprising:
a dielectric layer;
a first plurality of conductive features in a first part of the dielectric layer; and
a second plurality of conductive features in a second part of the dielectric layer, wherein in a top view of the structure, the second plurality of conductive features are wider than the first plurality of conductive features, and wherein the first plurality of conductive features are encircled by, and are joined to, respective ones of the second plurality of conductive features.

11. The structure of claim 10, wherein joining positions where the first plurality of conductive features are joined to the corresponding ones of the second plurality of conductive features are aligned to a ring.

12. The structure of claim 11, wherein the first plurality of conductive features and the second plurality of conductive features are elongated and have lengthwise directions perpendicular to respective portions of the ring.

13. The structure of claim 10, wherein ratios of first widths of the first plurality of conductive features to second widths of the second plurality of conductive features are in a range between about 1/10 and about 1/1.5.

14. The structure of claim 10, wherein the dielectric layer, the first plurality of conductive features, and the second plurality of conductive features are comprised in a redistribution structure, and wherein the structure further comprises a device die joined to the redistribution structure.

15. The structure of claim 10, wherein the first plurality of conductive features comprise first metal lines, and wherein first top surfaces of the first metal lines are lower than a second top surface of the dielectric layer.

16. A structure comprising:
a first dielectric layer;
a first plurality of conductive lines in the first dielectric layer;
a second plurality of conductive lines in the first dielectric layer, wherein the second plurality of conductive lines are joined to respective ones of the first plurality of conductive lines to form first interfaces, and wherein in a top view of the structure, the first interfaces are aligned to a first straight line;
a second dielectric layer over the first dielectric layer;
a third plurality of conductive lines in the second dielectric layer; and
a fourth plurality of conductive lines in the second dielectric layer, wherein the fourth plurality of conductive lines are joined to respective ones of the third plurality of conductive lines to form second interfaces, and wherein in the top view of the structure, the second interfaces are aligned to a second straight line.

17. The structure of claim 16, wherein in a cross-sectional view of the structure, the second straight line is directly over and overlaps the first straight line.

18. The structure of claim 16, wherein the third plurality of conductive lines are electrically connected to respective ones of the first plurality of conductive lines.

19. The structure of claim 16, wherein the first dielectric layer has a first top surface higher than second top surfaces of the first plurality of conductive lines and top surfaces of the second plurality of conductive lines.

20. The structure of claim 16, wherein in the top view of the structure, the first interfaces are aligned to a first ring, and the second interfaces are aligned to a second ring.
